(19) United States
(12) Patent Application Publication
(10) Pub. No.: US 2025/0299759 A1
(43) Pub. Date: Sep. 25, 2025

(54) STORAGE DEVICE INCLUDING REDUNDANCY MEMORY CELL AND REPAIR METHOD OF FAIL MEMORY CELL INCLUDED IN STORAGE DEVICE

(71) Applicant: SAMSUNG ELECTRONICS CO., LTD., SUWON-SI (KR)

(72) Inventors: DOHUI KIM, Suwon-si (KR); GYUSEONG KANG, Suwon-si (KR); HYUN-JIN SHIN, Suwon-si (KR)

(21) Appl. No.: 18/916,318

(22) Filed: Oct. 15, 2024

(30) Foreign Application Priority Data
Mar. 22, 2024 (KR) 10-2024-0039546

(51) Int. Cl. G11C 29/12; G11C 29/42

(52) U.S. Cl. CPC G11C 29/1201; G11C 29/42; G11C 2029/1202

(57) ABSTRACT

A storage device includes a main cell array including a plurality of main memory cells connected to a plurality of main wordlines, and a redundancy cell array including a plurality of redundancy memory cells connected to a plurality of redundancy wordlines. The redundancy wordlines are configured to replace a fail wordline including a fail memory cell among the main wordlines. The storage device further includes a repair information memory that stores repair-need-wordline information including matching information for the redundancy wordlines. The matching information is determined by identifying the fail word lines among the main wordlines, and selecting a repair-need-wordline having more fail bits than a specified fail bit criteria. A memory controller performs a read or write operation on a redundancy wordline corresponding to the repair-need-wordline when a request for the main cell array is identified as targeting the repair-need-wordline based on the repair-need-wordline information.

### CROSS-REFERENCE TO RELATED APPLICATIONS

This application claims priority under 35 U.S.C. § 119 to Korean Patent Application No. 10-2024-0039546 filed on Mar. 22, 2024, the disclosure of which is incorporated by reference herein in its entirety.

### TECHNICAL FIELD

Example embodiments of the present disclosure relate to a semiconductor memory device, and more particularly, to a storage device including redundant memory cells and a method of repairing fail memory cells included in the storage device.

### DISCUSSION OF RELATED ART

A semiconductor memory may be classified as a volatile memory or a non-volatile memory. While read and write speeds of a volatile memory (for example, a DRAM or an SRAM) may be fast, the data stored in the volatile memory is not saved when power is turned off. In contrast, a non-volatile memory (for example, an MRAM or a flash memory) may retain data even when the power is turned off.

An MRAM may include a magnetic tunnel junction (MTJ). The magnetization direction of the MTJ may change according to a direction of a current applied to the MTJ. A resistance value of the MTJ may vary according to the magnetization direction of the MTJ. The MRAM may store or read data using these MTJ characteristics.

### SUMMARY

Example embodiments of the present disclosure provide a storage device that may set fail bit criteria and preferentially repairs wordlines including fail bits greater than the fail bit criteria, and a repair method thereof.

According to an example embodiment, a storage device includes a main cell array including a plurality of main memory cells connected to a plurality of main wordlines, and a redundancy cell array including a plurality of redundancy memory cells connected to a plurality of redundancy wordlines. The redundancy wordlines are configured to replace a fail wordline, which includes a fail memory cell among, the plurality of main wordlines, and the fail wordline including the fail memory cell is one of a plurality of fail wordlines among the plurality of main wordlines. The storage device further includes a repair information memory configured to store repair-need-wordline information including matching information for the plurality of redundancy wordlines. The matching information is determined by identifying the fail wordlines among the plurality of main wordlines, and selecting, from among the identified fail wordlines, a repair-need-wordline having a number of fail bits greater than a specified fail bit criteria. The storage device further includes a memory controller configured to perform a read or write operation on a redundancy wordline corresponding to the repair-need-wordline when a read or write request, received for the main cell array, is identified as targeting the repair-need-wordline based on the repair-need-wordline information.

According to an example embodiment, a repair method of a storage device includes specifying a fail bit criteria, performing a read operation on a main wordline selected from among a plurality of main wordlines, detecting a number of fail bits of the selected main wordline by comparing output data resulting from the read operation and reference data, comparing the number of fail bits with the fail bit criteria, and determining whether to repair the selected main wordline when the number of fail bits is greater than the fail bit criteria.

According to an example embodiment, a storage device includes a main cell array including a plurality of main memory cells connected to a plurality of main wordlines, and a redundancy cell array including a plurality of redundancy memory cells connected to a plurality of redundancy wordlines. The redundancy wordlines are configured to replace a fail wordline, which includes a fail memory cell, among the plurality of main wordlines. The storage device further includes a repair logic configured to detect fail wordlines including fail bits among the plurality of main wordlines, select repair-need-wordlines in which a number of fail bits included in each of the fail wordlines is greater than a specified fail bit criteria, and generating repair-need-wordline information in which the repair-need-wordlines are matched in a one-to-one correspondence with the plurality of redundancy wordlines.

### BRIEF DESCRIPTION OF THE DRAWINGS

The above and other objects and features of the present disclosure will become apparent by describing in detail example embodiments thereof with reference to the accompanying drawings.

FIG. 1 is a block diagram illustrating a storage device according to an example embodiment of the present disclosure.

FIG. 2 is a block diagram illustrating an example embodiment of the memory device illustrated in FIG. 1.

FIG. 3 is a block diagram illustrating a method of repairing a fail memory cell included in the storage device of FIG. 1.

FIG. 4 is a diagram illustrating an example embodiment of a method of repairing a fail memory cell of FIG. 3.

FIG. 5 is a flowchart illustrating a method of repairing the fail memory cell of

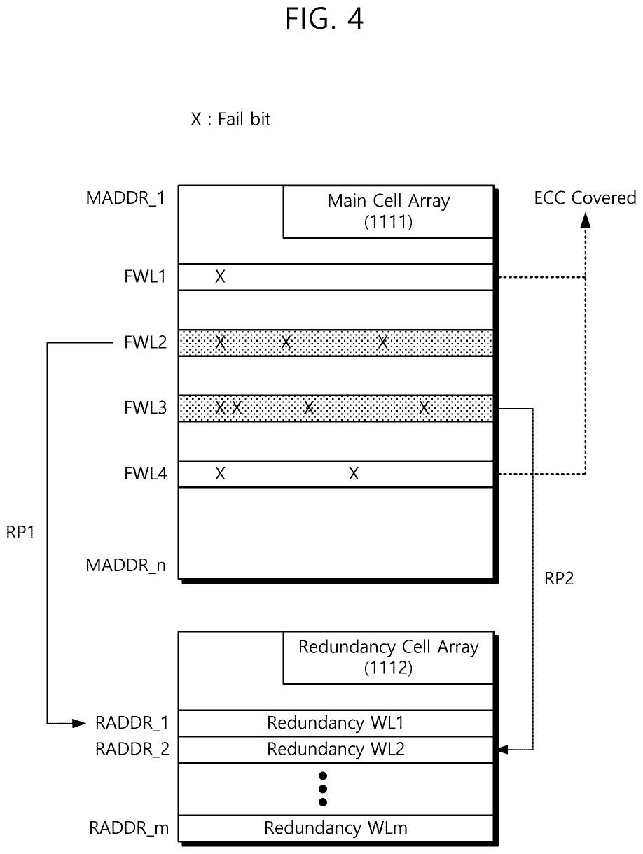

FIG. 4.

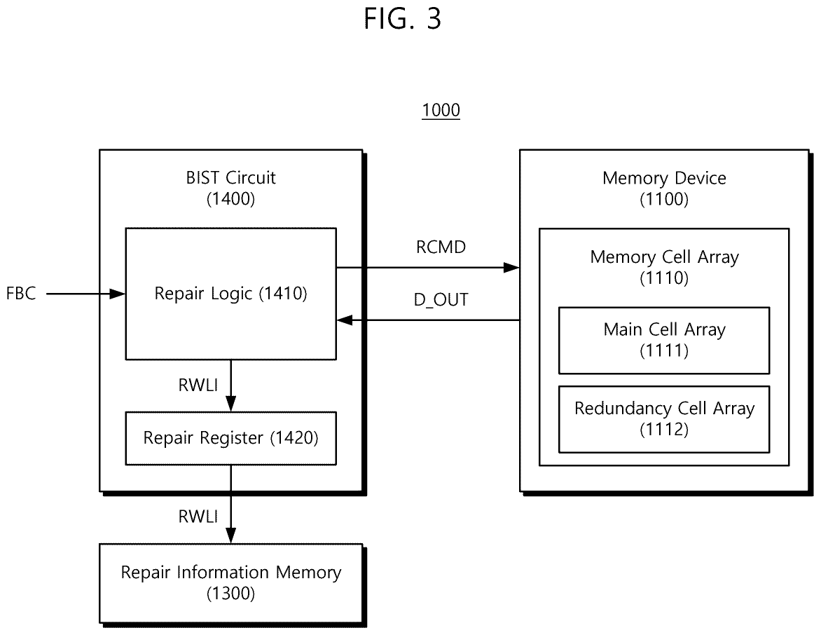

FIG. 6 is a diagram illustrating an example embodiment of a method of repairing a fail memory cell of FIG. 3.

FIG. 7 is a flowchart illustrating a method of repairing the fail memory cell of FIG. 6.

FIG. 8 is a flowchart detailing the operation S240 of FIG. 7.

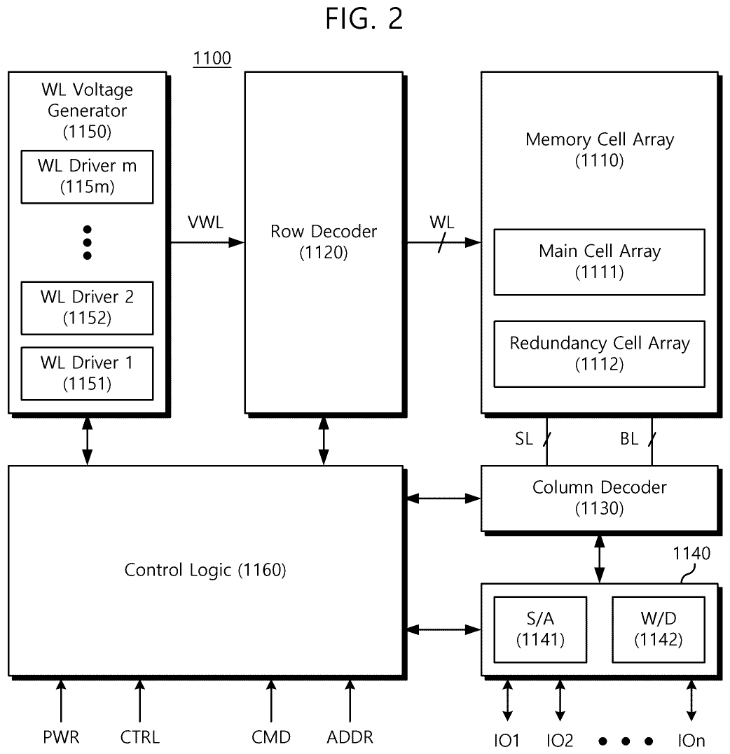

FIG. 9 is a circuit diagram illustrating an example embodiment of main memory cells of the memory cell array of FIG. 2.

FIG. 10 is a diagram illustrating an example embodiment of an operation of the first memory cell of FIG. 9.

FIG. 11 is a diagram illustrating an example embodiment of data according to states of the variable resistance element of FIG. 10.

FIG. 12 is a diagram illustrating a structure of the first memory cell of FIG. 9.

### DETAILED DESCRIPTION

Example embodiments of the present disclosure will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

As used herein, the term “and/or” includes any and all combinations of one or more of the associated listed items.

Spatially relative terms, such as “beneath”, “below”, “lower”, “under”, “above”, “upper”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below.

It will be understood that when a component such as a film, a region, a layer, etc., is referred to as being “on”, “connected to”, “coupled to”, or “adjacent to” another component, it can be directly on, connected, coupled, or adjacent to the other component, or intervening components may be present. Other words used to describe the relationships between components should be interpreted in a like fashion.

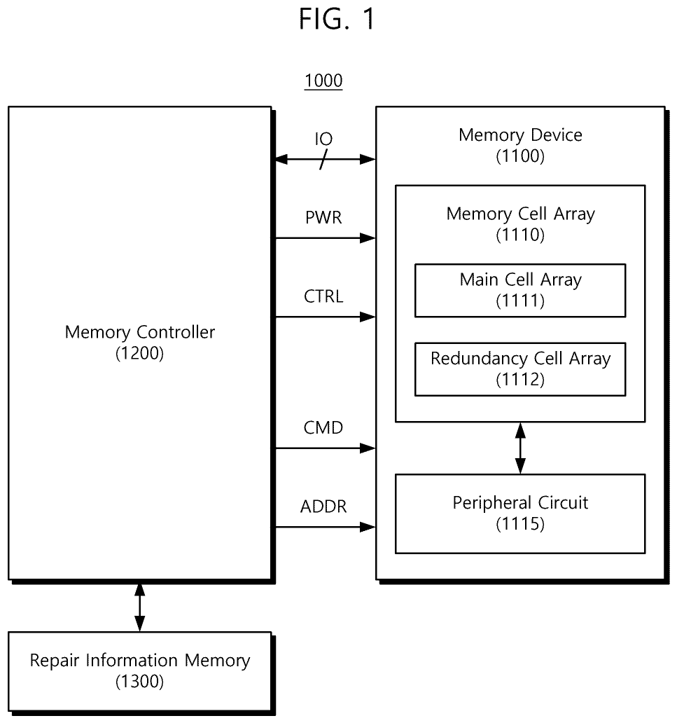

FIG. 1 is a block diagram illustrating a storage device according to an example embodiment of the present disclosure.

Referring to FIG. 1, a storage device 1000 may include a memory device 1100, a memory controller 1200 (also referred to as a memory controller circuit) and/or a repair information memory 1300.

According to an example embodiment, the memory device 1100 may receive input/output signals IO from the memory controller 1200 through input/output lines, receive control signals CTRL through control lines, and receive external power supply PWR through power lines. The storage device 1000 may store data in the memory device 1100 under the control of the memory controller 1200.

According to an example embodiment, the memory device 1100 may include a memory cell array 1110 and a peripheral circuit 1115. The memory cell array 1110 may have a planar two-dimensional structure or a vertical three-dimensional structure. The memory cell array 1110 may include a plurality of memory cells. Each memory cell may store single-bit data or multi-bit data.

According to an example embodiment, the memory cell array 1110 may be located (e.g., disposed) next to or above the peripheral circuit 1115 in terms of the design layout structure. A structure in which the memory cell array 1110 is positioned over the peripheral circuit 1115 may be referred to as a cell on peripheral (COP) structure. The memory cell array 1110 may be manufactured as a chip separate from the peripheral circuit 1115. An upper chip including the memory cell array 1110 and a lower chip including the peripheral circuit 1115 may be connected to each other by a bonding method. Such a structure may be referred to as a chip-to-chip (C2C) structure.

According to an example embodiment, the memory cell array 1110 may include a main cell array 1111 and/or a redundancy cell array 1112. The main cell array 1111 may include a plurality of main memory cells. The main cell array 1111 may be connected to a plurality of main wordlines. The redundancy cell array 1112 may include a plurality of redundant memory cells. The redundancy cell array 1112 may be connected to a plurality of redundancy wordlines.

According to an example embodiment, the main cell array 1111 may include a fail wordline including at least one fail memory cell. The redundancy cell array 1112 may replace at least one fail wordline on a wordline basis. A fail wordline may refer to a wordline that includes one or more defective memory cells (fail bits) and therefore fails to function correctly.

According to an example embodiment, the peripheral circuit 1115 may include an analog circuit(s) and/or a digital circuit(s) utilized to store data in the memory cell array 1110 or read data stored in the memory cell array 1110. The peripheral circuit 1115 may receive the external power PWR through power lines and generate internal power of various levels.

According to an example embodiment, the peripheral circuit 1115 may receive commands, addresses, and/or data from the memory controller 1200 through input/output lines. In an example embodiment, the peripheral circuit 1115 may store data in the memory cell array 1110 according to the control signals CTRL. In an example embodiment, the peripheral circuit 1115 may read data stored in the memory cell array 1110 and provide the read data to the memory controller 1200.

According to an example embodiment, the repair information memory 1300 may include address information of at least one repair-need-wordline repaired by the redundancy cell array 1112 among the main wordlines connected to the main cell array 1111. A repair-need-wordline may refer to a wordline that has been identified as needing repair based on fail bit criteria and is scheduled for repair by the redundancy cell array 1112. For example, the main wordlines connected to the main cell array 1111 may include fail wordlines including at least one fail memory cell. Some of the fail wordlines may be selected as a repair-need-wordline based on fail bit criteria.

According to an example embodiment, a selected repair-need-wordline may be matched in a one-to-one correspondence with one of the redundancy wordlines connected to the redundancy cell array 1112. Matching information between the repair-need-wordline and the redundancy wordline may be stored in the repair information memory 1300 as repair address information. As an example, the repair information memory 1300 may be implemented as a One Time Programmable (OTP) memory.

According to an example embodiment, when receiving a read request or write request from an external device (for example, a host or application processor), the memory controller 1200 may compare a read or write requested main address with repair address information stored in the repair information memory 1300. When the read or write requested main address is included in the repair address information stored in the repair information memory 1300, the memory controller 1200 may perform a read or write operation on a redundancy address being matched to the read or write requested main address. For example, the memory controller 1200 may perform a read or write operation on a redundancy wordline corresponding to the repair-need-wordline when a read or write request, received for the main cell array 1111, is identified as targeting the repair-need-wordline based on the repair-need-wordline information.

According to an example embodiment, the memory controller 1200 may correct errors included in the main cell array 1111 based on an error correction code ECC. For example, the memory controller 1200 may correct errors in the number of bits (for example, 1 bit or 2 bits) specified on a wordline basis using the ECC.

FIG. 2 is a block diagram illustrating an example embodiment of the memory device illustrated in FIG. 1.

The storage device 1000 of FIG. 1 may be a resistive storage device based on a resistive memory. For example, the memory device 1100 may be MRAM, ReRAM, or PRAM.

Referring to FIGS. 1 and 2, The memory device 1100 may include the memory cell array 1110 and the peripheral circuit 1115. The peripheral circuit 1115 may include a row decoder 1120, a column decoder 1130, an input/output circuit 1140, a wordline voltage generator 1150, and a control logic 1160.

According to an example embodiment, the memory cell array 1110 may include a plurality of memory blocks. Each memory block may include a plurality of memory cells. Each memory cell may store multi-bit data. Each memory block may be connected to a plurality of wordlines WL.

According to an example embodiment, the memory cell array 1110 may include a main cell array 1111 and a redundancy cell array 1112. The main cell array 1111 may include a fail wordline including at least one fail memory cell. The redundancy cell array 1112 may replace a specified number of fail wordlines.

According to an example embodiment, the row decoder 1120 may be connected to the memory cell array 1110 through the plurality of wordlines WL. The row decoder 1120 may select a main wordline during a write or read operation. The row decoder 1120 may receive a wordline voltage VWL from the wordline voltage generator 1150 and provide the wordline voltage VWL for the write or read operation to the selected main wordline.

According to an example embodiment, the column decoder 1130 may be connected to the memory cell array 1110 through a source line SL and/or a bitline BL. The column decoder 1130 may select the source line SL and/or the bitline BL in response to a selection signal provided from the control logic 1160. The column decoder 1130 may select source lines SL and/or bitlines BL using a plurality of NMOS transistors.

According to an example embodiment, the input/output circuit 1140 may be internally connected to the column decoder 1130 through data lines, and externally connected to the memory controller (refer to FIG. 1, 1200) through input/output lines IO1 to Ion, where n is a positive integer. The input/output circuit 1140 may receive write data from the memory controller 1200 during a write operation. Also, the input/output circuit 1140 may provide data read from the memory cell array 1110 to the memory controller 1200 during a read operation.

According to an example embodiment, the input/output circuit 1140 may include a sense amplifier 1141 and/or a write driver 1142. The input/output circuit 1140 may receive or output data from input/output terminals. The number of input/output terminals may vary depending on the type of storage device 1000. The input/output circuit 1140 may provide data to the write driver 1142 in response to a control signal or output data provided from the sense amplifier 1141.

According to an example embodiment, the sense amplifier 1141 may read data stored in the selected memory cell by sensing a difference between the voltage of the source line SL and a reference voltage Vref during a read operation. The reference voltage Vref may be provided from a reference voltage generator circuit. The sense amplifier 1141 may operate in response to a control signal provided from the control logic 1160.

According to an example embodiment, the write driver 1142 may receive a control signal from the control logic 1160 and provide a program current or program voltage to a data line. The program current or program voltage may be used to write the selected memory cell into one of multi-states. During an MLC write operation, the write driver 1142 may provide the program currents or program voltages one or more times according to the multi-state of the selected memory cell.

According to an example embodiment, the wordline voltage generator 1150 may receive internal power from the control logic 1160 and generate a wordline voltage VWL utilized to read or write data. The wordline voltage VWL may be provided to the selected wordline WL through the row decoder 1120. The wordline voltage generator 1150 may include a plurality of wordline drivers 1151 to 115m, where m is a positive integer.

According to an example embodiment, the control logic 1160 may control read and/or write operations of the memory device 1100 using commands CMD, addresses ADDR, and control signals CTRL provided from the memory controller 1200. The addresses ADDR may include a row address used to select one memory block or one wordline and a column address used to select one memory cell.

FIG. 3 is a block diagram illustrating a method of repairing a fail memory cell included in the storage device of FIG. 1.

Referring to FIG. 3, the storage device 1000 may include a memory device 1100, a repair information memory 1300 and/or a built-in self-test (BIST) circuit 1400 (hereinafter referred to as the BIST circuit).

According to an example embodiment, the memory device 1100 may include a memory cell array 1110 including a plurality of memory cells. The memory cell array 1110 may include a main cell array 1111 and a redundancy cell array 1112. The redundancy cell array 1112 may have memory cells smaller than those of the main cell array 1111. The redundancy cell array 1112 may replace a fail wordline including at least one fail memory cell among the main cell array 1111.

According to an example embodiment, the BIST circuit 1400 may set fail bit criteria FBC. For example, the BIST circuit 1400 may include a repair logic 1410 and/or a repair register 1420. The repair logic 1410 (also referred to as a repair logic circuit) may receive the fail bit criteria FBC from an external source (for example, a host or user). The BIST circuit 1400 may store the fail bit criteria FBC in a register of the repair logic 1410 or in the repair register 1420.

According to an example embodiment, the BIST circuit 1400 may perform a read operation to detect a fail memory cell included in the main cell array 1111. For example, the repair logic 1410 may transmit a read command RCMD to the memory device 1100 for all main wordlines connected to the main cell array 1111. As an example, the BIST circuit 1400 may sequentially transmit a read command RCMD corresponding to each of the main wordlines. The memory device 1100 may transmit output data D_OUT to the BIST circuit 1400 in response to the read command RCMD.

According to an example embodiment, the BIST circuit 1400 may detect at least one fail bit included in each of the fail wordlines connected to the main cell array 1111 based on the output data D_OUT. For example, main memory cells included in the main cell array 1111 may store initially specified data (for example, logic 0 or logic 1). The repair logic 1410 may compare the output data D_OUT and specified data to check the fail bits of each fail wordline connected to the main cell array 1111.

According to an example embodiment, the BIST circuit 1400 may determine whether to repair a fail wordline included in the main cell array 1111 based on fail bit criteria FBC. For example, the repair logic 1410 may count the number of fail bits detected in one main wordline (or address) based on the output data D_OUT. The repair logic 1410 may compare the number of fail bits detected in one main wordline (or address) with fail bit criteria FBC.

For example, in an example embodiment, when the number of fail bits detected in one main wordline (or address) is greater than the fail bit criteria FBC, the repair logic 1410 may repair the corresponding main wordline (or address). For example, in an example embodiment, when the number of fail bits detected in one main wordline (or address) is less than the fail bit criteria FBC, the repair logic 1410 does not repair the corresponding main wordline (or address).

According to an example embodiment, the repair logic 1410 may select at least one main wordline (or address) whose number of fail bits is greater than or equal to the fail bit criteria FBC as the repair-need-wordline (or address). The repair logic 1410 may match the repair-need-wordline (or address) to the redundancy wordline (or address) connected to the redundancy cell array 1112 on a one-to-one basis. The repair logic 1410 may store matching information between the repair-need-wordline (or address) and the redundancy wordline (or address) as repair-need-wordline information RWLI in the repair register 1420.

According to an example embodiment, after all redundancy wordlines (or addresses) connected to the redundancy cell array 1112 are matched, the BIST circuit 1400 may end the repair operation of the main cell array 1111. After the repair operation of the main cell array 1111 is completed, the BIST circuit 1400 may store the repair-need-wordline information RWLI stored in the repair register 1420 in the repair information memory 1300.

In an example embodiment, the BIST circuit 1400 may be included in the storage device 1000 and may be used to perform a repair operation of the main cell array 1111. In an example embodiment, the BIST circuit 1400 may be removed from the storage device 1000 after performing a repair operation on the main cell array 1111.

FIG. 4 is a diagram illustrating an example embodiment of a method of repairing a fail memory cell of FIG. 3.

Referring to FIGS. 3 and 4, the BIST circuit 1400 may detect fail wordlines (or addresses) including fail bits in the main wordlines (or addresses) connected to the main cell array 1111. The BIST circuit 1400 may repair a repair-need-wordline (or address) with a number of fail bits greater than the fail bit criteria FBC among the detected fail wordlines (or addresses) with a redundancy wordline (or address).

As an example in FIG. 4, the main cell array 1111 may be connected to n main wordlines corresponding to the first main address MADDR_1 to the n-th main address MADDR_n, where n is a positive integer. The redundancy cell array 1112 may be connected to m redundancy wordlines corresponding to the first redundancy address RADDR_1 to the m-th redundancy address RADDR_m, where m is a positive integer and m is less than n. The fail bit criteria FBC may be determined based on the number of fail bits that may be corrected by an error correction code ECC. For example, when an error of up to 2 bits may be corrected using an error correction code ECC, the fail bit criteria FBC may be set to 3 bits.

According to an example embodiment, the BIST circuit 1400 may detect the number of fail bits in each of the main addresses connected to the main cell array 1111 based on the output data D_OUT. For example, main memory cells included in the main cell array 1111 may store initially specified data (for example, logic 0 or logic 1). The repair logic 1410 may detect fail bits in each of the main addresses connected to the main cell array 1111 by comparing the output data D_OUT with specified data.

According to an example embodiment, the repair logic 1410 may count the number of fail bits in each of the main wordlines corresponding to the first main address MADDR_1 to the n-th main address MADDR_n. As an example, the repair logic 1410 may detect the first to fourth fail wordlines FWL1 to FWL4. The first fail wordline FWL1 may include one fail bit. The second fail wordline FWL2 may include three fail bits. The third fail wordline FWL3 may include four fail bits. The fourth fail wordline FWL4 may include two fail bits.

According to an example embodiment, the repair logic 1410 may select a repair-need-wordline from among the detected fail wordlines based on fail bit criteria FBC (for example, 3 bits). For example, the repair logic 1410 may select the second fail wordline FWL2 and the third fail wordline FWL3 including three or more fail bits as repair-need-wordlines.

According to an example embodiment, the repair logic 1410 may match the selected repair-need-wordline to the redundancy wordline. For example, the repair logic 1410 may match the second fail wordline FWL2 to the first redundancy wordline corresponding to the first redundancy address RADDR_1 through the first repair operation RP1. The repair logic 1410 may match the third fail wordline FWL3 to the second redundancy wordline corresponding to the second redundancy address RADDR_2 through the second repair operation RP2. The repair logic 1410 may store matching information between the repair-need-wordline and the redundancy wordline (or the repair address and the redundancy address) as repair-need-wordline information RWLI in the repair register 1420.

According to an example embodiment, after all redundancy wordlines (or addresses) connected to the redundancy cell array 1112 are matched, the BIST circuit 1400 may end the repair operation of the main cell array 1111. After the repair operation of the main cell array 1111 is completed, the BIST circuit 1400 may store the repair-need-wordline information RWLI stored in the repair register 1420 in the repair information memory 1300.

According to an example embodiment, based on the repair-need-wordline information RWLI stored in the repair information memory 1300, the memory controller 1200 of FIG. 1 may repair a fail wordline (for example, the second fail wordline FWL2 and/or the third fail wordline FWL3) that cannot be corrected, which may be referred to as a non-correctable fail word line, by an error correction code ECC during a read or write operation of the memory device 1100 with a redundancy wordline (or address). Additionally, the memory controller 1200 may correct errors in correctable fail wordlines (for example, the first fail wordline FWL1 and the fourth fail wordline FWL4) using an error correction code ECC.

As described above, the repair logic 1410 may repair some fail wordlines (for example, main wordlines that may not be recovered by other recovery methods) selected based on the fail bit criteria FBC among the detected fail wordlines. Accordingly, the redundancy cell array 1112 may be preferentially assigned to the unrecoverable defective address of the main cell array 1111 by another recovery method. The memory controller 1200 of FIG. 1 may recover unselected fail wordlines based on fail bit criteria FBC through another recovery method (for example, ECC) during a read or write operation. Accordingly, the redundancy cell array 1112 may be used efficiently.

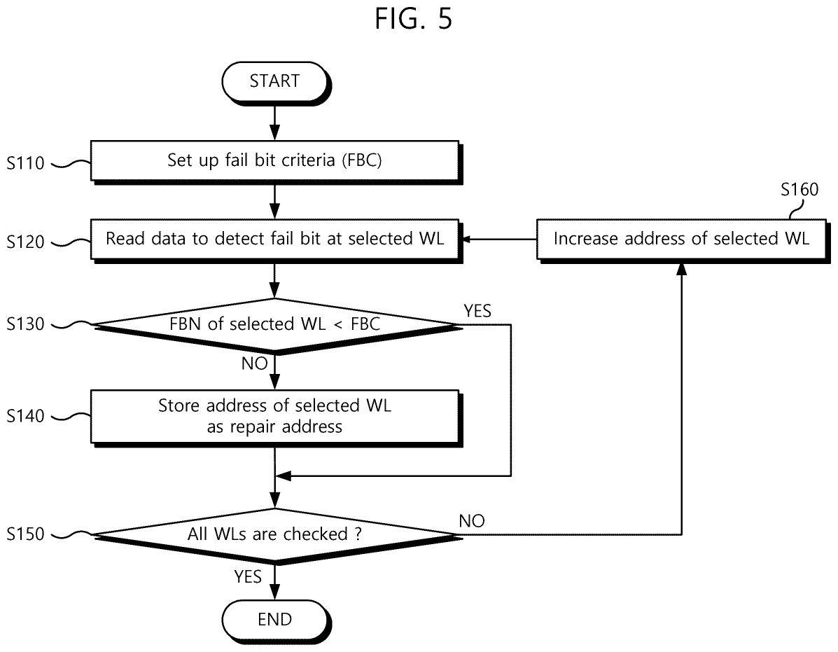

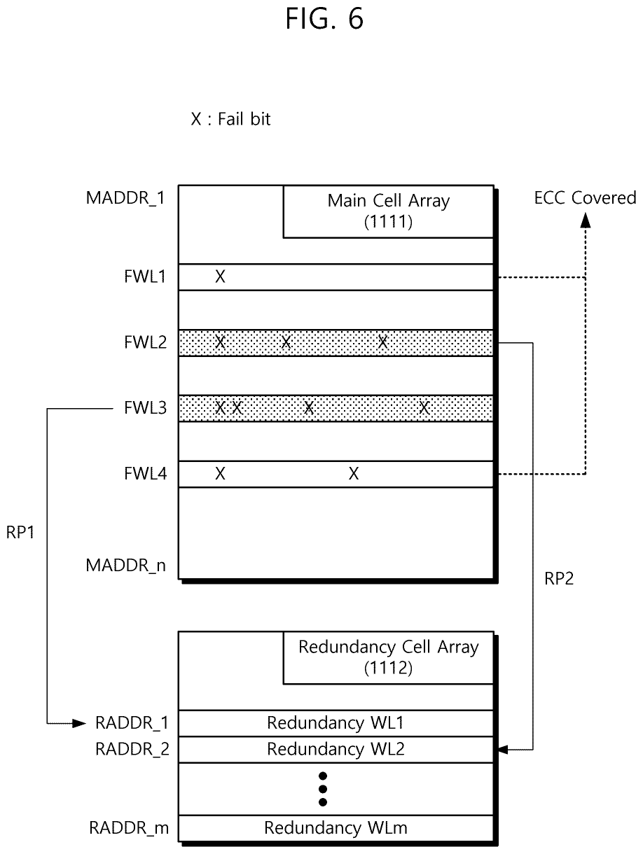

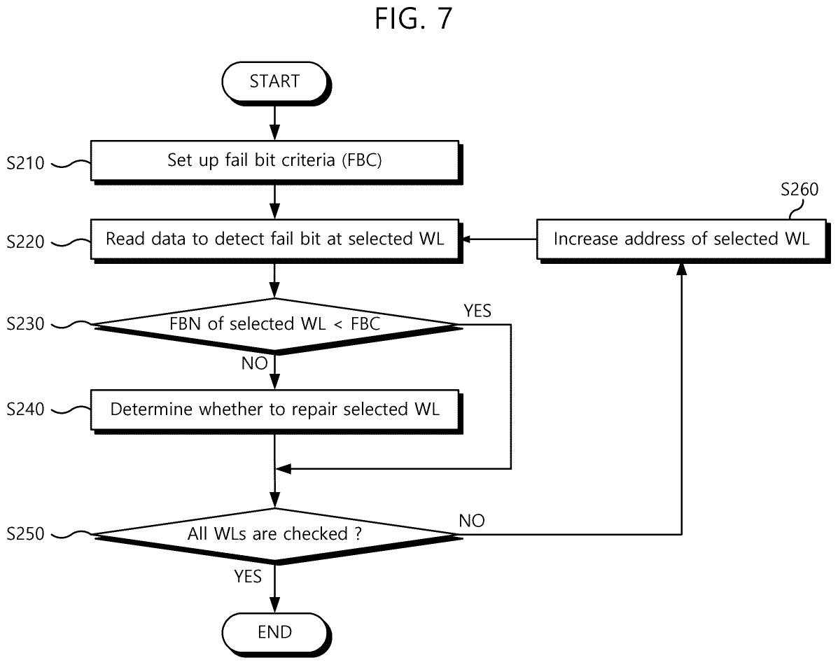

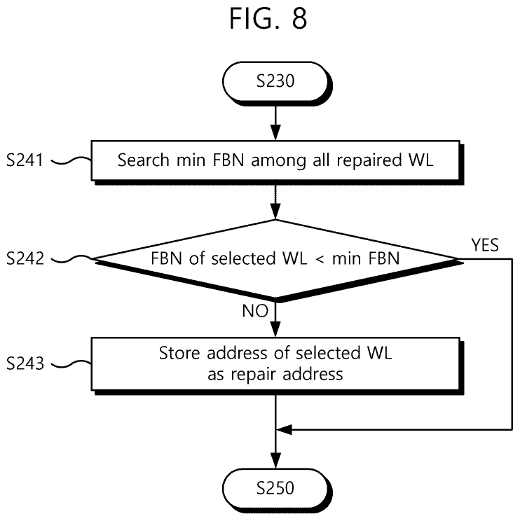

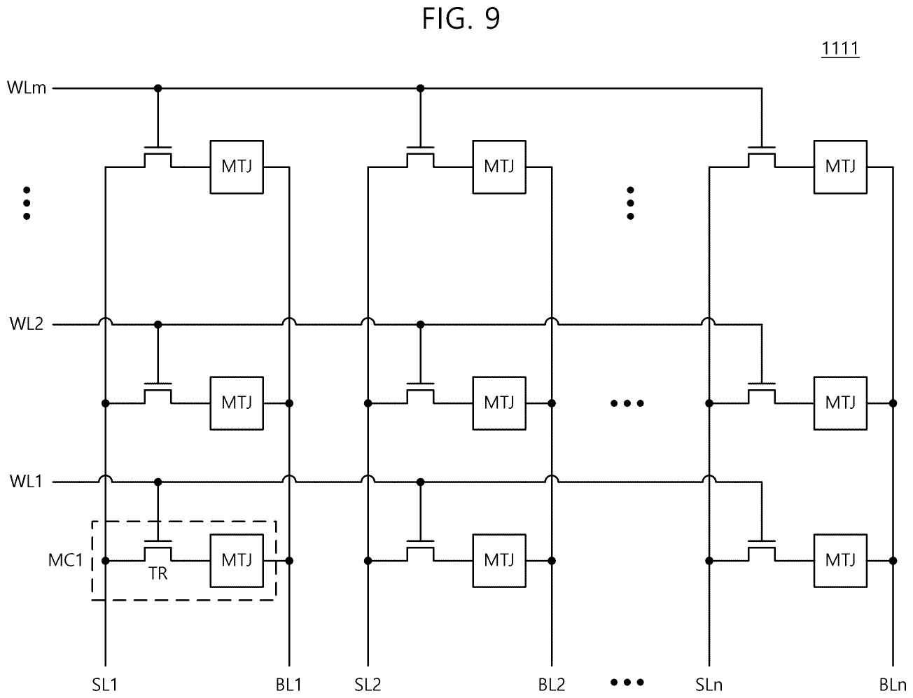

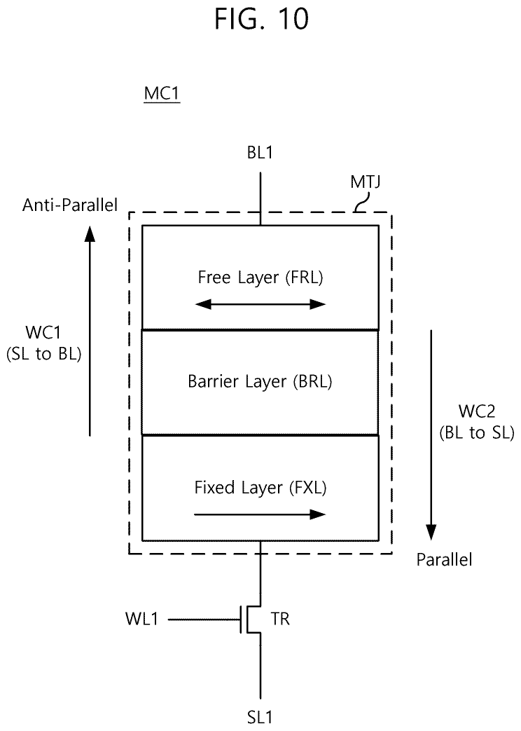

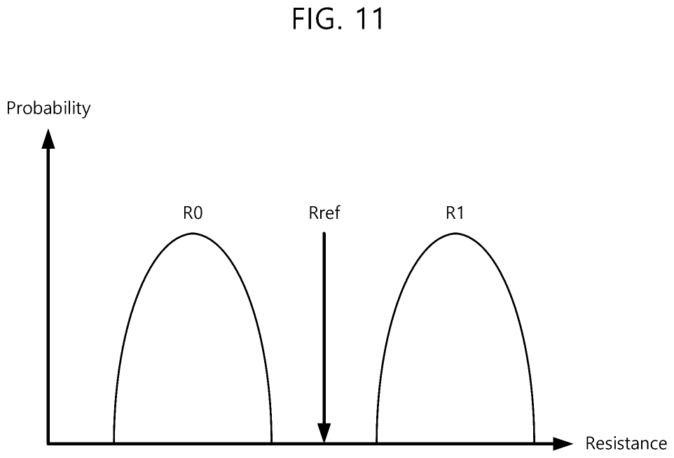

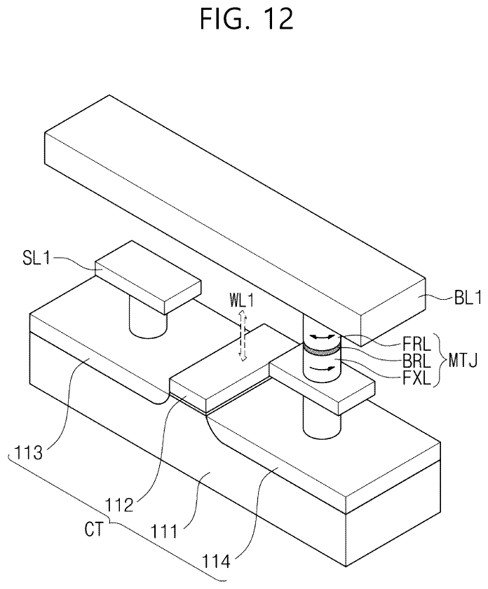

FIG. 5 is a flowchart illustrating a method of repairing the fail memory cell of FIG. 4.

Referring to FIGS. 3 to 5, the BIST circuit 1400 may detect fail wordlines (or addresses) including fail bits in the main wordlines (or addresses) connected to the main cell array 1111. The BIST circuit 1400 may repair a repair-need-wordline (or address) with a number of fail bits greater than the fail bit criteria FBC among the detected fail wordlines (or addresses) with a redundancy wordline (or address).

According to an example embodiment, in operation S110, the BIST circuit 1400 (or repair logic 1410) may set fail bit criteria FBC. The BIST circuit 1400 (or repair logic 1410) may receive fail bit criteria FBC from an external source (for example, a host or user). For example, the fail bit criteria FBC may be determined based on the number of bits (for example, 1 bit or 2 bits) that may be corrected through an error correction code ECC in the memory controller 1200 of FIG. 1.

According to an example embodiment, in operation S120, the BIST circuit 1400 (or repair logic 1410) may perform a read operation of the main cell array 1111 to detect a fail bit in the selected main wordline. For example, the BIST circuit 1400 (or repair logic 1410) may sequentially transmit a read command RCMD corresponding to each of the main wordlines connected to the main cell array 1111. The memory device 1100 may transmit output data D_OUT to the BIST circuit 1400 in response to the read command RCMD. The BIST circuit 1400 (or repair logic 1410) may perform a read operation starting from the first main wordline connected to the main cell array 1111.

According to an example embodiment, in operation S130, the BIST circuit 1400 (or repair logic 1410) may compare the fail bit number FBN of the selected main wordline with the fail bit criteria FBC. When the fail bit number FBN of the selected main wordline is greater than or equal to the fail bit criteria FBC, the BIST circuit 1400 (or repair logic 1410) may perform operation S140. When the fail bit number FBN of the selected main wordline is less than the fail bit criteria FBC, the BIST circuit 1400 (or repair logic 1410) may perform operation S150.

According to an example embodiment, in operation S140, when the fail bit number FBN of the selected main wordline is greater than or equal to the fail bit criteria FBC, the BIST circuit 1400 (or repair logic 1410) may store a main address of the selected main wordline as a repair address. For example, the BIST circuit 1400 (or repair logic 1410) may match the main address of the selected main wordline to the redundancy wordline (or address) connected to the redundancy cell array 1112 on a one-to-one basis. The BIST circuit 1400 (or repair logic 1410) may store matching information between the repair address and the redundancy address as repair-need-wordline information RWLI in the repair register 1420.

According to an example embodiment, in operation S150, the BIST circuit 1400 (or repair logic 1410) may check whether the fail bit number FBN of all main wordlines connected to the main cell array 1111 has been detected. When the fail bit number FBN of all main wordlines connected to the main cell array 1111 is detected, the BIST circuit 1400 (or repair logic 1410) may terminate the repair operation of the fail memory cell. When there is a main wordline on which the detection operation of the fail bit number FBN has not been performed, the BIST circuit 1400 (or repair logic 1410) may perform operation S160.

According to an example embodiment, in operation S160, the BIST circuit 1400 (or repair logic 1410) may increase the main address of the selected main wordline. Alternatively, the BIST circuit 1400 (or repair logic 1410) may select the next main wordline. The BIST circuit 1400 (or repair logic 1410) may repeatedly perform operations S120 to S150 for the next main wordline.

FIG. 6 is a diagram illustrating an example embodiment of a method of repairing a fail memory cell of FIG. 3.

Referring to FIGS. 3 and 6, the BIST circuit 1400 may detect fail wordlines (or addresses) including fail bits in the main wordlines (or addresses) connected to the main cell array 1111. The BIST circuit 1400 may repair a repair-need-wordline (or address) with a number of fail bits greater than the fail bit criteria FBC among the detected fail wordlines (or addresses) with a redundancy wordline (or address). Additionally, in an example embodiment, the BIST circuit 1400 may preferentially repair fail wordlines including the most fail bits.

In FIG. 6, the main cell array 1111 may be connected to n main wordlines corresponding to the first main address MADDR_1 to the n-th main address MADDR_n, where n is a positive integer. The redundancy cell array 1112 may be connected to m redundancy wordlines corresponding to the first redundancy address RADDR_1 to the m-th redundancy address RADDR_m, where m is a positive integer and m is less than n. The fail bit criteria FBC may be determined based on the number of fail bits that may be corrected by an error correction code ECC. For example, when an error of up to 2 bits may be corrected using an error correction code ECC, the fail bit criteria FBC may be set to 3 bits.

According to an example embodiment, the BIST circuit 1400 may detect the number of fail bits in each of the main addresses connected to the main cell array 1111 based on the output data D_OUT. For example, main memory cells included in the main cell array 1111 may store initially specified data (for example, logic 0 or logic 1). The repair logic 1410 may detect fail bits in each of the main addresses connected to the main cell array 1111 by comparing the output data D_OUT with specified data.

According to an example embodiment, the repair logic 1410 may count the number of fail bits in each of the main wordlines corresponding to the first main address MADDR_1 to the n-th main address MADDR_n. As an example, the repair logic 1410 may detect the first to fourth fail wordlines FWL1 to FWL4. The first fail wordline FWL1 may include one fail bit. The second fail wordline FWL2 may include three fail bits. The third fail wordline FWL3 may include four fail bits. The fourth fail wordline FWL4 may include two fail bits.

According to an example embodiment, the repair logic 1410 may select a repair-need-wordline from among the detected fail wordlines based on fail bit criteria FBC (for example, 3 bits). For example, the repair logic 1410 may select the second fail wordline FWL2 and the third fail wordline FWL3 including three or more fail bits as repair-need-wordlines.

According to an example embodiment, the repair logic 1410 may sequentially match the repair-need-wordline including the largest number of fail bits to the redundancy wordline among the selected repair-need-wordlines. For example, the repair logic 1410 may match the third fail wordline FWL3 to the first redundancy wordline corresponding to the first redundancy address RADDR_1 through the first repair operation RP1. The repair logic 1410 may match the second fail wordline FWL2 to the second redundancy wordline corresponding to the second redundancy address RADDR_2 through the second repair operation RP2. The repair logic 1410 may store matching information between the repair-need-wordline and the redundancy wordline (or the repair address and the redundancy address) as repair-need-wordline information RWLI in the repair register 1420.

According to an example embodiment, after all redundancy wordlines (or addresses) connected to the redundancy cell array 1112 are matched, the BIST circuit 1400 may end the repair operation of the main cell array 1111. After the repair operation of the main cell array 1111 is completed, the BIST circuit 1400 may store the repair-need-wordline information RWLI stored in the repair register 1420 in the repair information memory 1300.

According to an example embodiment, based on the repair-need-wordline information RWLI stored in the repair information memory 1300, the memory controller 1200 of FIG. 1 may repair fail wordlines (for example, the second fail wordline FWL2 and the third fail wordline FWL3) that cannot be corrected, which may be referred to as non-correctable fail word lines, by an error correction code ECC during a read or write operation of the memory device 1100 with a redundancy wordline (or address). Additionally, the memory controller 1200 may correct errors in correctable fail wordlines (for example, the first fail wordline FWL1 and the fourth fail wordline FWL4) using an error correction code ECC.

As described above, the repair logic 1410 may repair some fail wordlines (for example, main wordlines that cannot be recovered by other recovery methods) selected based on the fail bit criteria FBC among the detected fail wordlines. Accordingly, the redundancy cell array 1112 may be preferentially assigned to the unrecoverable defective address of the main cell array 1111 that cannot be repaired by another recovery method. Additionally, the repair logic 1410 may select the final repair-need-wordlines in order of the number of fail bits among the fail wordlines selected based on the fail bit criteria FBC. Accordingly, when there are more fail wordlines than redundancy resources (for example, redundancy cell array 1112), the storage device 1000 may efficiently repair fail wordlines that are difficult to recover through other recovery methods (for example, ECC).

FIG. 7 is a flowchart illustrating a method of repairing the fail memory cell of FIG. 6.

FIG. 8 is a flowchart detailing the operation S240 of FIG. 7.

Referring to FIGS. 3 and 6 to 8, the BIST circuit 1400 may detect fail wordlines (or addresses) including fail bits in the main wordlines (or addresses) connected to the main cell array 1111. The BIST circuit 1400 may repair a repair-need-wordline (or address) with a number of fail bits greater than the fail bit criteria FBC among the detected fail wordlines (or addresses) with a redundancy wordline (or address). Additionally, the BIST circuit 1400 may preferentially repair fail wordlines including the most fail bits.

According to an example embodiment, in operation S210, the BIST circuit 1400 (or repair logic 1410) may set fail bit criteria FBC. The BIST circuit 1400 (or repair logic 1410) may receive fail bit criteria FBC from an external source (for example, a host or user). For example, the fail bit criteria FBC may be determined based on the number of bits (for example, 1 bit or 2 bits) that may be corrected through an error correction code ECC in the memory controller 1200 of FIG. 1.

According to an example embodiment, in operation S220, the BIST circuit 1400 (or repair logic 1410) may perform a read operation of the main cell array 1111 to detect a fail bit in the selected main wordline. For example, the BIST circuit 1400 (or repair logic 1410) may sequentially transmit a read command RCMD corresponding to each of the main wordlines connected to the main cell array 1111. The memory device 1100 may transmit output data D_OUT to the BIST circuit 1400 in response to the read command RCMD. The BIST circuit 1400 (or repair logic 1410) may perform a read operation starting from the first main wordline connected to the main cell array 1111.

According to an example embodiment, in operation S230, the BIST circuit 1400 (or repair logic 1410) may compare the fail bit number FBN of the selected main wordline with the fail bit criteria FBC. When the fail bit number FBN of the selected main wordline is greater than or equal to the fail bit criteria FBC, the BIST circuit 1400 (or repair logic 1410) may perform operation S240. When the fail bit number FBN of the selected main wordline is less than the fail bit criteria FBC, the BIST circuit 1400 (or repair logic 1410) may perform operation S250.

According to an example embodiment, in operation S240, when the fail bit number FBN of the selected main wordline is greater than or equal to the fail bit criteria FBC, the BIST circuit 1400 (or repair logic 1410) may determine whether to repair the selected main wordline. The BIST circuit 1400 (or repair logic 1410) may determine whether to repair the selected main wordline through operations S241 to S243.

According to an example embodiment, in operation S241, the BIST circuit 1400 (or repair logic 1410) may search for the minimum fail bit number (min FBN) among the currently repaired wordlines. For example, the BIST circuit 1400 (or repair logic 1410) may determine the minimum fail bit number (min FBN) by sequentially comparing the fail bit number FBN of each repaired wordline.

According to an example embodiment, in operation S242, the BIST circuit 1400 (or repair logic 1410) may compare the fail bit number FBN of the selected main wordline with the minimum fail bit number (min FBN). When the fail bit number FBN of the selected main wordline is greater than or equal to the minimum fail bit number (min FBN), the BIST circuit 1400 (or repair logic 1410) may perform operation S243. When the fail bit number FBN of the selected main wordline is less than the minimum fail bit number (min FBN), the BIST circuit 1400 (or repair logic 1410) may perform operation S250.

According to an example embodiment, in operation S243, when the fail bit number FBN of the selected main wordline is greater than or equal to the minimum fail bit number (min FBN), the BIST circuit 1400 (or repair logic 1410) may save the main address of the selected main wordline as a repair address. For example, the BIST circuit 1400 (or repair logic 1410) may match the main address of the selected main wordline to the redundancy wordline (or address) connected to the redundancy cell array 1112 on a one-to-one basis. The BIST circuit 1400 (or repair logic 1410) may store matching information between the repair address and the redundancy address as repair-need-wordline information RWLI in the repair register 1420.

According to an example embodiment, in operation S250, the BIST circuit 1400 (or repair logic 1410) may check whether the fail bit number FBN of all main wordlines connected to the main cell array 1111 has been detected. When the fail bit number FBN of all main wordlines connected to the main cell array 1111 is detected, the BIST circuit 1400 (or repair logic 1410) may terminate the repair operation of the fail memory cell. When there is a main wordline on which the detection operation of the fail bit number FBN has not been performed, the BIST circuit 1400 (or repair logic 1410) may perform operation S260.

According to an example embodiment, in operation S260, the BIST circuit 1400 (or repair logic 1410) may increase the main address of the selected main wordline. Alternatively, the BIST circuit 1400 (or repair logic 1410) may select the next main wordline. The BIST circuit 1400 (or repair logic 1410) may repeatedly perform operations S220 to S250 for the next main wordline.

FIG. 9 is a circuit diagram illustrating an example embodiment of main memory cells of the memory cell array of FIG. 2.

FIGS. 9 to 12 are diagrams for explaining the first memory cell of FIG. 9.

FIG. 10 is a diagram illustrating an example embodiment of an operation of the first memory cell of FIG. 9.

FIG. 11 is a diagram illustrating an example embodiment of data according to states of the variable resistance element of FIG. 10.

FIG. 12 is a diagram illustrating a structure of the first memory cell of FIG. 9.

Referring to FIGS. 9 to 12, the memory cell array 1110 may include a main cell array 1111. Each of the main memory cells included in the main cell array 1111 may be an MRAM cell and may be connected to wordlines WL1 to WLm, bitlines BL1 to BLn, and source lines SL1 to SLn, respectively, where each of m and n is a positive integer.

According to an example embodiment, the first memory cell MC1 may include an access transistor TR and a variable resistance element (for example, MTJ; Magnetic Tunnel Junction). One end of the access transistor TR may be connected to the first source line SL1, the other end of the access transistor TR may be connected to one end of the variable resistance element MTJ, and the gate of the access transistor TR may be connected to the first source line SL1. MC1 May be connected to wordline WL1. The other end of the variable resistance element MTJ may be connected to the first bitline BL1.

According to an example embodiment, data may be stored in each of the plurality of memory cells by adjusting the resistance value of the variable resistance element MTJ. For example, as illustrated in FIGS. 4 and 6, the variable resistance element MTJ may include a free layer FRL, a barrier layer BRL, and a fixed layer FXL. The barrier layer BRL is located between the free layer FRL and the fixed layer FXL, the free layer FRL is connected to the first bitline BL1, and the fixed layer FXL is connected to the other end of the access transistor TR.

According to an example embodiment, the magnetization direction of the fixed layer FXL may be fixed to a specific direction, and the magnetization direction of the free layer FRL may be changed according to specific conditions (for example, the direction of write current). In an example embodiment, the variable resistance element MTJ may further include an anti-ferromagnetic layer that may be used to fix the magnetization direction of the fixed layer FXL.

According to an example embodiment, the free layer FRL may include a material having a changeable magnetization direction. The magnetization direction of the free layer FRL may be changed by electrical/magnetic factors provided outside and/or inside the memory cell. The free layer FRL may include a ferromagnetic material including at least one of, for example, cobalt (Co), iron (Fe), and nickel (Ni). For example, the free layer FRL is at least one selected from FeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO and Y3Fe5O12. However, the scope of the present disclosure is not limited thereto.

According to an example embodiment, the thickness of the barrier layer BRL may be thinner than the spin diffusion distance. The barrier layer BRL may include a non-magnetic material. For example, the barrier layer BRL may be composed of oxides such as magnesium oxide (MgO), titanium oxide (TiO), aluminum oxide (Al₂O₃), magnesium-zinc oxide (MgZnO), or magnesium-boron oxide (MgBO). Additionally, the barrier layer BRL may include nitrides containing titanium (Ti) or vanadium (V). However, the scope of the present disclosure is not limited thereto.

According to an example embodiment, the fixed layer FXL may have a magnetization direction fixed by an antiferromagnetic layer. The fixed layer FXL may include a ferromagnetic material. For example, the fixed layer FXL is at least of CoFeB, Fe, Co, Ni, Gd, Dy, CoFe, NiFe, MnAs, MnBi, MnSb, CrO2, MnOFe2O3, FeOFe2O3, NiOFe2O3, CuOFe2O3, MgOFe2O3, EuO and Y3Fe5O12. In an example embodiment, the antiferromagnetic layer may include an anti-ferromagnetic material. For example, the antiferromagnetic layer may include at least one of PtMn, IrMn, MnO, MnS, MnTe, MnF2, FeCl2, FeO, CoCl2, CoO, NiCl2, NiO, and Cr. However, the scope of the present disclosure is not limited thereto.

As illustrated in FIG. 10, the magnetization direction of the free layer FRL may change depending on the direction of the write currents WC1 and WC2 flowing through the variable resistance element MTJ. For example, when the current flows in the direction from the first source line SL1 to the first bitline BL1, such as the first write current WC1 illustrated in FIG. 10, the magnetization direction of the free layer FRL is opposite to the magnetization direction of the fixed layer FXL, and this state may be an anti-parallel (ap) state. On the contrary, when the current flows in the direction from the first bitline BL1 to the first source line SL1, as in the second write current WC2 illustrated in FIG. 10, the magnetization direction of the free layer FRL becomes the same as the magnetization direction of the fixed layer FXL, and this state may be a parallel (p) state.

According to an example embodiment, when the variable resistance element MTJ is in a semi-balanced state, the variable resistance element MTJ may have an anti-balance resistance Rap, as illustrated in FIG. 11. When the variable resistance element MTJ is in a balanced state, the variable resistance element MTJ may have a balance resistance Rp. The memory device 1100 may distinguish data 0 or data 1 using the size of the resistance value.

According to an example embodiment, the memory device 1100 may perform a read operation by comparing the resistance of a memory cell with a reference resistance Rref that has a value between the resistance levels representing data 0 and data 1. The reference resistance Rref may be changed externally instead of using a fixed value during manufacturing of the memory device 1100. The reference resistance may be determined through a test operation. The data in the first memory cell MC1 may be stored based on the resistance value of the variable resistance element MTJ. By measuring this resistance value, the memory device can read and retrieve the data stored in the first memory cell MC1.

Referring to FIG. 12, the access transistor CT may include a body substrate 111, a gate electrode 112, and junctions 113 and 114. The junction 113 may be formed on the body substrate 111 and may be connected to the first source line SL1. The junction 114 may be formed on the body substrate 111 and may be connected to the first bitline BL1 through an MTJ element. The gate electrode 112 may be formed on the body substrate 111 between the junctions 113 and 114 and may be connected to the first wordline WL1.

According to example embodiments of the present disclosure, a device is provided which may use redundancy resources to repair fail wordlines efficiently.

As is traditional in the field of the present disclosure, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

While the present disclosure has been described with reference to example embodiments thereof, it will be apparent to those of ordinary skill in the art that various changes 5 and modifications may be made thereto without departing from the spirit and scope of the present disclosure as set forth in the following claims.

What is claimed is:

1. A storage device, comprising:
a main cell array including a plurality of main memory cells connected to a plurality of main wordlines;
a redundancy cell array including a plurality of redundancy memory cells connected to a plurality of redundancy wordlines,
wherein the redundancy wordlines are configured to replace a fail wordline, which includes a fail memory cell, among the plurality of main wordlines,
wherein the fail wordline including the fail memory cell is one of a plurality of fail wordlines among the plurality of main wordlines;
a repair information memory configured to store repair-need-wordline information including matching information for the plurality of redundancy wordlines,
wherein the matching information is determined by identifying the fail wordlines among the plurality of main wordlines, and selecting, from among the identified fail wordlines, a repair-need-wordline having a number of fail bits greater than a specified fail bit criteria; and
a memory controller configured to perform a read or write operation on a redundancy wordline corresponding to the repair-need-wordline when a read or write request, received for the main cell array, is identified as targeting the repair-need-wordline based on the repair-need-wordline information.

2. The storage device of claim 1, wherein the fail bit criteria is determined based on the number of fail bits, which is recovered by the memory controller with an error correction code.

3. The storage device of claim 1, wherein the memory controller is further configured to restore fail bits by using an error correction code in fail wordlines which have a number of fail bits smaller than the fail bit criteria among the fail wordlines.

4. The storage device of claim 1, wherein the repair-need-wordline is one of a plurality of repair-need-wordlines, and a wordline corresponding to a lower address among the repair-need-wordlines is preferentially matched with one of the plurality of redundancy wordlines.

5. The storage device of claim 1, wherein the repair-need-wordline is one of a plurality of repair-need-wordlines, and a wordline with a largest number of fail bits among the repair-need-wordlines is preferentially matched with one of the plurality of redundancy wordlines.

6. A repair method of a storage device, the method comprising:
specifying a fail bit criteria;
performing a read operation on a main wordline selected from among a plurality of main wordlines;
detecting a number of fail bits of the selected main wordline by comparing output data resulting from the read operation and reference data;
comparing the number of fail bits with the fail bit criteria; and
determining whether to repair the selected main wordline when the number of fail bits is greater than the fail bit criteria.

7. The method of claim 6, wherein determining whether to repair the selected main wordline includes matching the selected main wordline with one of a plurality of redundancy wordlines.

8. The method of claim 6, wherein determining whether to repair the selected main wordline includes searching for a minimum number of fail bits among the numbers of fail bits corresponding to previously repaired fail wordlines.

9. The method of claim 8, wherein determining whether to repair the selected main wordline includes, when the number of fail bits of the selected main wordline is greater than or equal to the minimum number of fail bits, matching the selected main wordline with one of a plurality of redundancy wordlines.

10. The method of claim 6, wherein, when the number of fail bits is less than the fail bit criteria, determining whether to repair the selected main wordline does not match the selected main wordline with a plurality of redundancy wordlines.

11. A storage device, comprising:
a main cell array including a plurality of main memory cells connected to a plurality of main wordlines;
a redundancy cell array including a plurality of redundancy memory cells connected to a plurality of redundancy wordlines,
wherein the redundancy wordlines are configured to replace a fail wordline, which includes a fail memory cell, among the plurality of main wordlines; and
a repair logic configured to detect fail wordlines including fail bits among the plurality of main wordlines, select repair-need-wordlines in which a number of fail bits included in each of the fail wordlines is greater than a specified fail bit criteria, and generate repair-need-wordline information in which the repair-need-wordlines are matched in a one-to-one correspondence with the plurality of redundancy wordlines.

12. The storage device of claim 11, wherein the repair logic is further configured to preferentially match a wordline corresponding to a lower address among the repair-need-wordlines with one of the plurality of redundancy wordlines.

13. The storage device of claim 11, wherein the repair logic is further configured to preferentially match a wordline with a largest number of fail bits among the repair-need-wordlines with one of the plurality of redundancy wordlines.

14. The storage device of claim 11, wherein the repair logic is further configured to sequentially compare data of a selected main wordline among the plurality of main wordlines with reference data to count the number of fail bits.

15. The storage device of claim 14, wherein the repair logic is further configured to determine whether to repair the selected main wordline when the number of fail bits in the selected main wordline is greater than the fail bit criteria.

16. The storage device of claim 15, wherein the repair logic is further configured to search for a minimum number of fail bits among the numbers of fail bits corresponding to previously repaired fail wordlines.

17. The storage device of claim 16, wherein the repair logic is further configured to match the selected main wordline with one of the plurality of redundancy wordlines when the number of fail bits of the selected main wordline is greater than or equal to the minimum number of fail bits.

18. The storage device of claim 11, further comprising:
a repair register configured to store the repair-need-wordline information.

19. The storage device of claim 18, further comprising:
a repair information memory configured to store the repair-need-wordline information,
wherein the repair logic is further configured to sequentially store information of the repair-need-wordlines selected among the fail wordlines in the repair register, and after detection of all fail bits of the plurality of main wordlines is completed, store the repair-need-wordline information in the repair information memory.

20. The storage device of claim 19, further comprising:
a memory controller configured to:
control read or write operations of the main cell array; and
perform read or write operations of the plurality of redundancy wordlines corresponding to the repair-need-wordlines upon determining, based on the repair-need-wordline information, that a received read or write request for the main cell array corresponds to the repair-need-wordlines.
